(19) United States
(12) Patent Application Publication
(10) Pub. No.: US 2022/0263520 A1
(43) Pub. Date: Aug. 18, 2022

(54) SYSTEM-LEVEL CHOPPING IN COULOMB COUNTER CIRCUIT

(71) Applicant: Cirrus Logic International Semiconductor Ltd., Edinburgh (GB)

(72) Inventors: Axel THOMSEN, Austin, TX (US); John L. MELANSON, Austin, TX (US); Mujo KOZAK, Austin, TX (US); Paul WILSON, Linlithgow (GB); Eric J. KING, Austin, TX (US)

(73) Assignee: Cirrus Logic International Semiconductor Ltd., Edinburgh (GB)

(21) Appl. No.: 17/232,949

(22) Filed: Apr. 16, 2021

Related U.S. Application Data
(60) Provisional application No. 63/148,832, filed on Feb. 12, 2021.

(51) Int. Cl. H03M 3/00; G01R 31/3828; G01R 31/36

(52) U.S. Cl. CPC H03M 3/458; G01R 31/3648; G01R 31/3828

(57) ABSTRACT

A signal processing system may include a sensor readout channel configured to convert an electronic signal into a digital quantity, the sensor readout channel comprising an analog-to-digital converter (ADC) having an input and an output, first outside chopping switches located at the input of the ADC, and second outside chopping switches located at the output of the ADC. The ADC may comprise a memory element, first inside chopping switches located at the input of the memory element, and second inside chopping switches located at the output of the memory element. The first outside chopping switches, the second outside chopping switches, the first inside chopping switches, and the second inside chopping switches may be switched at the same frequency such that the memory element is swapped periodically in synchronization with the first outside chopping switches and second outside chopping switches.

### FIELD OF DISCLOSURE

The present disclosure relates in general to circuits for electronic devices, including without limitation personal portable devices such as wireless telephones and media players, and more specifically, to system-level chopping techniques for a coulomb counter that may be used in battery management.

### BACKGROUND

Portable electronic devices, including wireless telephones, such as mobile/cellular telephones, tablets, cordless telephones, mp3 players, and other consumer devices, are in widespread use. Such portable electronic devices are often powered by a battery (e.g., a lithium-ion battery). In battery-powered devices, it is often desirable to measure an amount of electrical charge drawn from a battery and delivered to the battery, which may be used to determine a state of charge of the battery.

A circuit referred to as a coulomb counter may be used to measure an amount of electrical charge drawn from a battery and delivered to the battery. In operation, a coulomb counter may detect an electrical current flowing in and out of the battery and integrate such current continuously over time, in order to calculate a total electrical charge drawn from and delivered to the battery. Because coulomb counters continuously integrate, extremely low direct-current (DC) offset in coulomb counter circuitry is desired.

FIG. 1 illustrates a block diagram of an example coulomb counter, as is known in the art. As shown in FIG. 1, a coulomb counter 1 may include a sense resistor 2 for measuring a sense voltage V_{SNS} which is indicative of an electrical current I_{SNS} flowing through the sense resistor. For example, electrical current I_{SNS} may comprise a current drawn from a battery. As also shown in FIG. 1, coulomb counter 1 may include an integrator 4 implemented in part with an amplifier 6, such integrator 4 configured to integrate electrical current I_{SNS} over time, providing an indication of net electrical charge that has flowed through sense resistor 2. Thus, if sense resistor 2 is coupled to the output of a battery, coulomb counter 1 may calculate a net electrical charge drawn from the battery.

As also shown in FIG. 1, coulomb counter 1 may implement both system-level chopping using chopping blocks 8 and block-level chopping within integrator 4, using chopping blocks 10. Block-level chopping blocks 10 may operate at a first chopping frequency (e.g., one-half the sampling frequency Fₛ of coulomb counter 1) to reduce DC offset and inverse frequency noise (also known as 1/f noise) of amplifier 6, and system-level chopping blocks 8 may operate at a second chopping frequency (e.g., Fₛ/512) to provide residual DC offset for coulomb counter 1.

For better clarity, coulomb counter 1 depicted in FIG. 1 may be represented as a signal processing block diagram as shown in FIG. 2. As shown in FIG. 2, system-level chopping blocks 8 are represented as mixers 12, each having a chopping frequency f_{chsys}, at the input and output of a sigma-delta analog to digital converter (ADC) 14 that comprises integrator 4 and a three-level quantizer 16. Block-level chopping blocks 10 are not depicted in FIG. 2.

Coulomb counter 1 as shown in FIGS. 1 and 2 may have disadvantages. Among such disadvantages are an elevated quantization error. Thus, approaches that overcome such disadvantages are desired.

### SUMMARY

In accordance with the teachings of the present disclosure, certain disadvantages and problems associated with existing sensor systems may be reduced or eliminated.

In accordance with embodiments of the present disclosure, a signal processing system may include a sensor readout channel configured to convert an electronic signal into a digital quantity, the sensor readout channel comprising an analog-to-digital converter (ADC) having an input and an output, first outside chopping switches located at the input of the ADC, and second outside chopping switches located at the output of the ADC. The ADC may comprise a memory element, first inside chopping switches located at the input of the memory element, and second inside chopping switches located at the output of the memory element. The first outside chopping switches, the second outside chopping switches, the first inside chopping switches, and the second inside chopping switches may be switched at the same frequency such that the memory element is swapped periodically in synchronization with the first outside chopping switches and second outside chopping switches.

In accordance with embodiments of the present disclosure, a method may be provided for use in a system comprising a sensor readout channel configured to convert an electronic signal into a digital quantity, wherein the sensor readout channel includes an analog-to-digital converter (ADC) having an input and an output, first outside chopping switches located at the input of the ADC, and second outside chopping switches located at the output of the ADC, and wherein the ADC includes a memory element, first inside chopping switches located at the input of the memory element, and second inside chopping switches located at the output of the memory element. The method may include switching the first outside chopping switches, the second outside chopping switches, the first inside chopping switches, and the second inside chopping switches at the same frequency such that the memory element is swapped periodically in synchronization with the first outside chopping switches and second outside chopping switches.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the example, present embodiments and certain advantages thereof may be acquired by referring to the following description taken in conjunction with the accompanying drawings, in which like reference numbers indicate like features, and wherein:

FIG. 1 illustrates a circuit diagram of selected components of a coulomb counter, as in known in the art;

FIG. 2 illustrates a block diagram of the coulomb counter of FIG. 1, as in known in the art;

FIG. 3 illustrates a block diagram of an example coulomb counter, in accordance with embodiments of the present disclosure;

FIG. 4A illustrates a circuit diagram of selected components of a sigma-delta ADC, in accordance with embodiments of the present disclosure;

FIG. 4B illustrates a circuit diagram of selected components of another sigma-delta ADC, in accordance with embodiments of the present disclosure;

FIG. 5 illustrates an example graph depicting measured output charge versus input charge for the coulomb counter shown in FIGS. 1 and 2; and

FIG. 6 illustrates an example graph depicting measured output charge versus input charge for the coulomb counter shown in FIGS. 3 and 4A-4B, in accordance with embodiments of the present disclosure.

### DETAILED DESCRIPTION

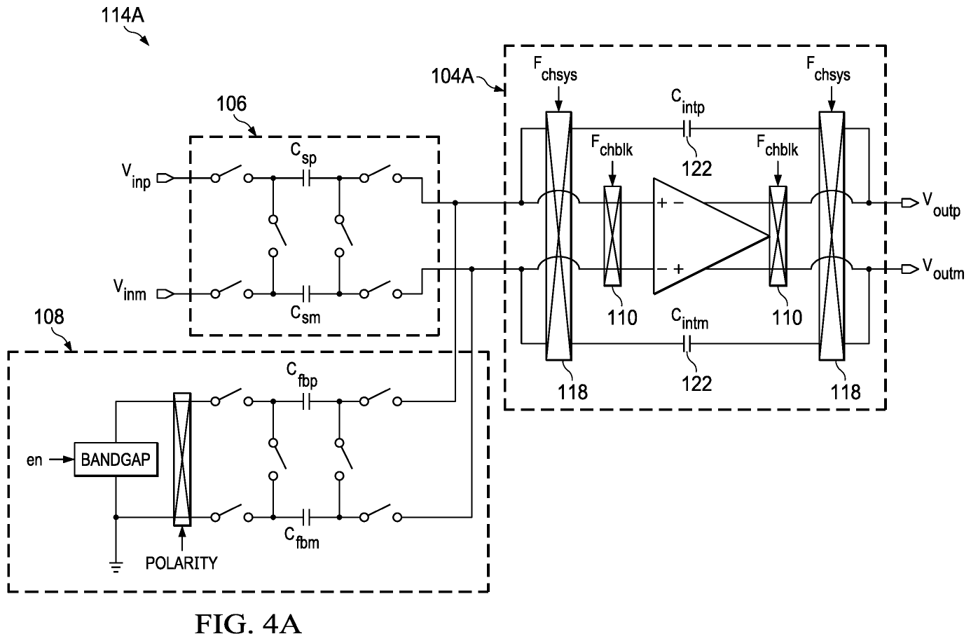

FIG. 3 illustrates a block diagram of an example coulomb counter 100, in accordance with embodiments of the present disclosure. In some embodiments, coulomb counter 100 may be implemented within a portable electronic device, such as a smart phone, tablet, game controller, and/or other suitable device. As shown in FIG. 3, coulomb counter 100 may include an anti-aliasing filter 102, outside system-level chopping mixers 112, sigma-delta ADC 114, and an accumulator 120.

Anti-aliasing filter 102 may be located at the input of coulomb counter 100 and may be configured to filter an input signal to coulomb counter 100 indicative of an electrical current (e.g., a sensed voltage across a sense resistor). Outside system-level chopping mixers 112 may be located at an input and output of sigma-delta ADC 114 to perform signal chopping at a system-level chopping frequency f_{chsys}.

Sigma-delta ADC 114 may comprise any suitable system, device, or apparatus configured to convert an analog signal received at its input to an equivalent digital signal at its output. As shown in FIG. 3, sigma-delta ADC 114 may be implemented using a gain element 106, a gain element 108, combiner 109, integrator 104, a three-level quantizer 116, and two inside system-level chopping mixers 118.

Gain element 106 may comprise any suitable system, device, or apparatus configured to apply a gain b1 (which may be less than, greater than, or equal to 1) to a signal received at the input of sigma-delta ADC 114. Similarly, gain element 108 may comprise any suitable system, device, or apparatus configured to apply a gain al (which may be less than, greater than, or equal to 1) to a signal generated at the output of sigma-delta ADC 114.

Combiner 109 may generate an error signal equal to a difference between the input signal to sigma-delta ADC 114 as modified by gain element 106 and the output signal of sigma-delta ADC 114 as modified by gain element 108. Such error signal may be operated upon by integrator 104 and three-level quantizer 116 to generate a quantized digital output signal for sigma-delta ADC 114. Accumulator 120 may receive the quantized digital output signal and digitally integrate the quantized digital output signal over time to calculate a net amount of charge Q flowing through the sense resistor from which the input of coulomb counter 100 is obtained.

Inside system-level chopping mixers 118 may be located internally to sigma-delta ADC 114 at an input and output of integrator 104 to perform signal chopping at a system-level chopping frequency f_{chsys}. As described below, such inside system-level chopping mixers 118 may serve to preserve quantization error within coulomb counter 100, even when system-level chopping is activated.

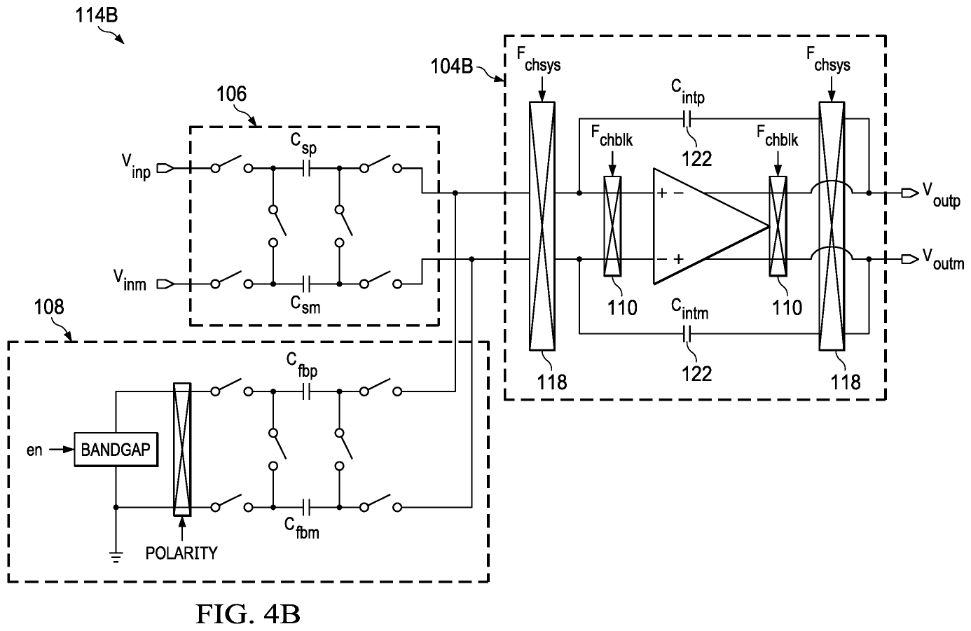

FIG. 4A illustrates a circuit diagram of selected components of sigma-delta ADC 114A, showing detailed implementation of gain element 106, gain element 108, integrator 104A, inside system-level chopping mixers 118, and block-level chopping mixers 110, in accordance with embodiments of the present disclosure. As shown in FIG. 4A, inside system-level chopping mixers 118 may be implemented as a set of switches at the input and output of integrator 104A, wherein such set of switches may swap integrating capacitors 122 of integrator 104A every time the input signal to sigma-delta ADC 114 changes polarity due to the outside system-level chopping mixer 118 at the input of sigma-delta ADC 114.

FIG. 4B illustrates a circuit diagram of selected components of sigma-delta ADC 114B, showing detailed implementation of gain element 106, gain element 108, integrator 104B, inside system-level chopping mixers 118, and block-level chopping mixers 110, in accordance with embodiments of the present disclosure. Sigma-delta ADC 114B of FIG. 4B may be similar in many respects to sigma-delta ADC 114A of FIG. 4A, with a main difference being the connectivity of components within integrator 104B may be different than that within integrator 104A.

While the embodiments shown and described above are shown for a switched-capacitor integrator, it is understood that systems and methods of the present disclosure may also be applied to a continuous-time implementation of an integrator.

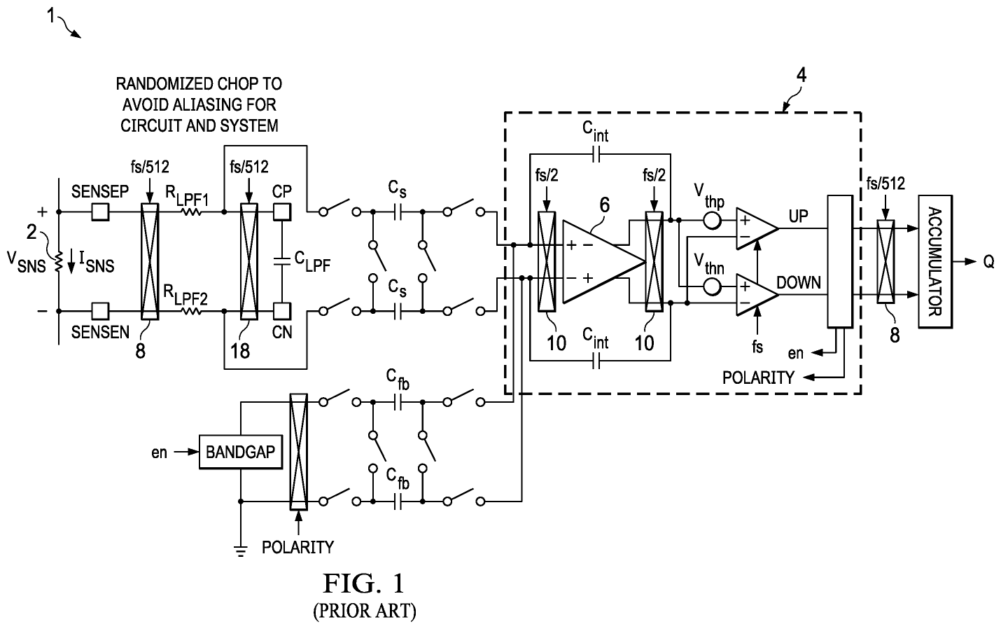

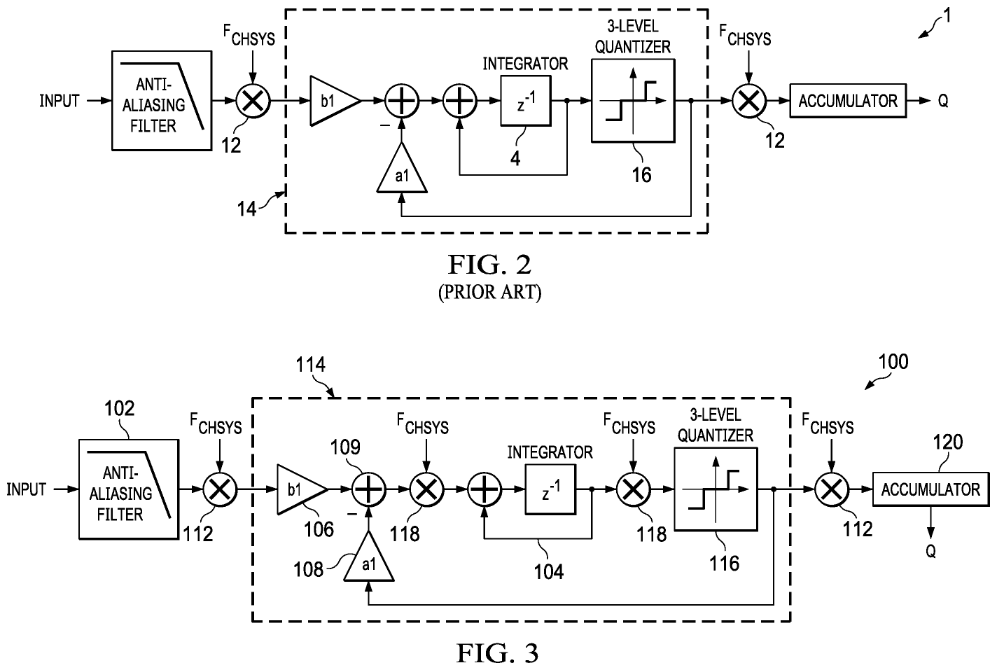

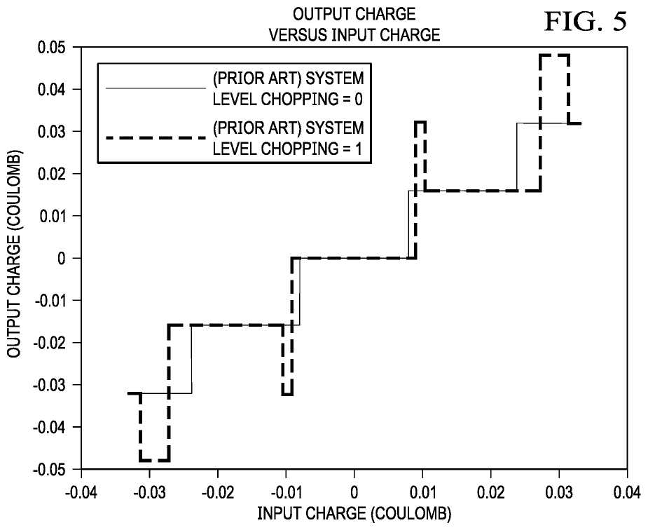

FIG. 5 illustrates an example graph depicting measured output charge versus input charge for the coulomb counter shown in FIGS. 1 and 2. As shown in FIG. 5, using the prior art system of FIGS. 1 and 2, when system-level chopping is deactivated, minimum charge resolution may be equal to 16 mC. However, as shown in FIG. 5, when system-level chopping is activated, non-monotonic behavior in a transfer characteristic of coulomb counter 1 may be present, resulting in a minimum charge resolution that may be either 32 mC or −16 mC.

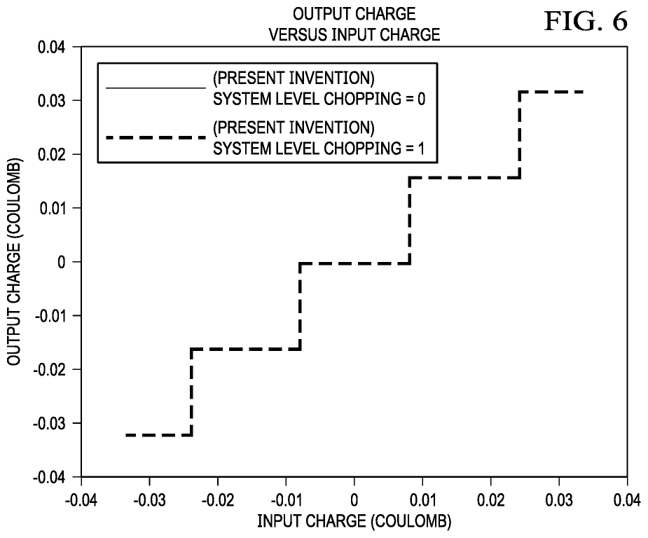

On the other hand, FIG. 6 illustrates an example graph depicting measured output charge versus input charge for the coulomb counter shown in FIGS. 3 and 4A-4B, in accordance with embodiments of the present disclosure. As shown in FIG. 6, the transfer curves for when system-level chopping is deactivated and when system-level chopping is activated may align, and thus a monotonic transfer characteristic is preserved, and minimum charge resolution may be equal to 16 mC, regardless of whether system-level chopping is activated or deactivated.

Although the foregoing discussion contemplates system-level chopping in a coulomb counter circuit, it is understood that the system-level chopping techniques disclosed above may apply to any sensor readout channel including a sigma-delta ADC wherein the sensor readout channel employs outside system-level chopping switches at the input and output of the sigma-delta ADC. In is understood that any such sensor readout channel may include memory elements (e.g., capacitors) used to implement an integrator inside the sigma-delta ADC which may be swapped periodically using inside system-level chopping switches in synchronization with the outside system-level chopping switches.

Although the foregoing contemplates sensing paths with two chopping operations within the path, it is understood that the foregoing dynamic chopping techniques could be applied to a sensing path or other signal path with a single chopping operation, or multiple chopping operations.

Further, although the foregoing contemplates use of system-level chopping techniques with a sigma-delta ADC, the systems and methods herein may be applied to any ADC having a memory element, whether such memory element includes an integrator or some other memory element.

Further, although the foregoing contemplates use of system-level chopping techniques with a first-order ADC having a single integrator, it is understood that such techniques may be used with higher-order ADCs including additional integrators or memory elements, in which case each memory element (each integrator or other memory element) may have inside system-level chopping mixers 118 at the respective input and output of such memory element.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages. Additionally, other technical advantages may become readily apparent to one of ordinary skill in the art after review of the foregoing figures and description.

To aid the Patent Office and any readers of any patent issued on this application in interpreting the claims appended hereto, applicants wish to note that they do not intend any of the appended claims or claim elements to invoke 35 U.S.C. § 112(f) unless the words “means for” or “step for” are explicitly used in the particular claim.

What is claimed is:

1. A signal processing system comprising:
a sensor readout channel configured to convert an electronic signal into a digital quantity, the sensor readout channel comprising:
an analog-to-digital converter (ADC) having an input and an output;
first outside chopping switches located at the input of the ADC; and
second outside chopping switches located at the output of the ADC;
wherein the ADC comprises:
a memory element;
first inside chopping switches located at the input of the memory element; and
second inside chopping switches located at the output of the memory element; and
wherein the first outside chopping switches, the second outside chopping switches, the first inside chopping switches, and the second inside chopping switches are switched at the same frequency such that the memory element is swapped periodically in synchronization with the first outside chopping switches and the second outside chopping switches.

2. The signal processing system of claim 1, wherein the memory element comprises an integrator.

3. The signal processing system of claim 1, further comprising an impedance for converting a sensed physical quantity into the electronic signal.

4. The signal processing system of claim 3, wherein:
the electronic signal is a voltage; and
the impedance is a resistor configured to convert an electrical current into the voltage.

5. The signal processing system of claim 4, wherein the sensor readout channel further comprises a digital accumulator configured to digitally integrate an ADC output signal generated at the output of the ADC to generate the digital quantity representing a net amount of charge that has flowed through the impedance.

6. The signal processing system of claim 4, wherein the digital quantity represents a net amount of charge that has been delivered from a battery coupled to the impedance.

7. The signal processing system of claim 1, wherein the ADC is a sigma-delta ADC.

8. The signal processing system of claim 1, wherein the ADC comprises:
a second memory element;
third inside chopping switches located at the input of the second memory element; and
fourth inside chopping switches located at the output of the second memory element; and
wherein the first outside chopping switches, the second outside chopping switches, the first inside chopping switches, the second inside chopping switches, the third inside chopping switches, and the fourth inside chopping switches are switched at the same frequency such that the memory element and the second memory element are swapped periodically in synchronization with the first outside chopping switches and second outside chopping switches.

9. The signal processing system of claim 8, wherein:
the memory element comprises a first integrator; and
the second memory element comprises a second integrator.

10. A method comprising, in a system comprising a sensor readout channel configured to convert an electronic signal into a digital quantity, wherein the sensor readout channel includes an analog-to-digital converter (ADC) having an input and an output, first outside chopping switches located at the input of the ADC, and second outside chopping switches located at the output of the ADC, and wherein the ADC includes a memory element, first inside chopping switches located at the input of the memory element, and second inside chopping switches located at the output of the memory element:
switching the first outside chopping switches, the second outside chopping switches, the first inside chopping switches, and the second inside chopping switches at the same frequency such that the memory element is swapped periodically in synchronization with the first outside chopping switches and the second outside chopping switches.

11. The method of claim 10, wherein the memory element comprises an integrator.

12. The method of claim 10, further comprising converting a sensed physical quantity into the electronic signal with an impedance.

13. The method of claim 12, wherein:
the electronic signal is a voltage;
the impedance is a resistor; and
the method further comprises converting an electrical current into the voltage with the resistor.

14. The method of claim 13, further comprising digitally integrating, with a digital accumulator of the sensor readout channel, an ADC output signal generated at the output of the ADC to generate the digital quantity representing a net amount of charge that has flowed through the impedance.

15. The method of claim 13, wherein the digital quantity represents a net amount of charge that has been delivered from a battery coupled to the impedance.

16. The method of claim 10, wherein the ADC is a sigma-delta ADC.

17. The method of claim 10, wherein the ADC comprises:
a second memory element;
third inside chopping switches located at the input of the second memory element; and
fourth inside chopping switches located at the output of the second memory element; and
the method comprises switching the first outside chopping switches, the second outside chopping switches, the first inside chopping switches, the second inside chopping switches, the third inside chopping switches, and the fourth inside chopping switches at the same frequency such that the memory element and the second memory element are swapped periodically in synchronization with the first outside chopping switches and second outside chopping switches.

18. The method of claim 17, wherein:
the memory element comprises a first integrator; and
the second memory element comprises a second integrator.
